(19) United States
(12) Patent Application Publication
(10) Pub. No.: US 2013/0081665 A1
(43) Pub. Date: Apr. 4, 2013

(54) THERMOELECTRIC ELEMENT

(71) Applicant: Gerhard Span, Wattens (AT)

(72) Inventor: Gerhard Span, Wattens (AT)

(73) Assignee: O-FLEXX TECHNOLOGIES GMBH, Duisburg (DE)

(21) Appl. No.: 13/701,674

(22) PCT Filed: May 12, 2011
(86) PCT No.: PCT/EP2011/057679

§ 371 Date: Dec. 3, 2012

(30) Foreign Application Priority Data
Jun. 4, 2010 (DE) 10 2010 022 668.8

(51) Int. Cl. H01L 35/32

(52) U.S. Cl. CPC H01L 35/325; H01L 35/32
USPC 136/205; 136/224

(57) ABSTRACT

A thermoelectric element includes at least one thermocouple comprising an n-doped and a p-doped thermal leg made of semiconductor material, wherein the thermal legs extend between a hot and a cold side of the thermoelectric element and different temperatures can applied and tapped between the hot and the cold side. In order to create a thermoelectric element haying a high thermal power density that nevertheless ensures sufficient mechanical stability using less semiconductor material, the thermoelectric effect and the support function of the block between two components is split. The support function is performed by a multipart support, while the thermoelectric effect is initiated by thermal legs disposed on the support, in particular designed as a thin film

The invention relates to a thermoelectric element having at least one thermocouple which has an n-doped thermocouple leg and a p-doped thermocouple leg made of semiconductor material, the thermocouple legs extending between a hot side and a cold side of the thermoelectric element, and different temperatures being able to be applied or tapped off between the hot and cold sides, and the thermoelectric element comprising a carrier.

The method of operation of thermoelectric elements is based on the thermoelectric effect:

In the case of the Seebeck effect, an electrical voltage is produced between two points of an electrical conductor or semiconductor which have different temperatures. Whereas the Seebeck effect describes the production of a voltage, the Peltier effect solely occurs as a result of the flow of an external current. Both effects always occur in a thermocouple through which current flows. The Peltier effect occurs when two conductors or semiconductors with different electronic thermal capacities are brought into contact and electrons flow from one conductor/semiconductor to the other as a result of an externally applied electric current. Suitable materials, in particular semiconductor materials, are used to produce temperature differences with electric current or, conversely, to produce electric current from temperature differences.

Heat can be directly converted into electrical energy using a thermoelectric generator having a plurality of thermoelectric elements. The thermoelectric elements preferably consist of differently doped semiconductor materials, as a result of which it is possible to considerably increase the efficiency in comparison with thermocouples having two different metals connected to one another at one end. Conventional semiconductor materials are Bi2Te3, PbTe, SiGe, BiSb or FeSi2. In order to obtain sufficiently high voltages, a plurality of thermoelectric elements are combined to form a module and are electrically connected in series and, if appropriate, also in parallel.

A conventional thermoelectric element consists of two or more small cuboids which are made of p-doped and n-doped semiconductor material and are alternately connected to one another at the too and bottom by means of metal bridges. The metal bridges simultaneously form the thermal contact areas on a hot or cold side of the thermoelectric element and are usually arranged between two ceramic plates arranged at a distance from one another. One n-doped cuboid and one p-doped cuboid, also referred to as thermocouple legs, in each case form a thermocouple, the cuboids extending between the of and cold sides of the thermoelectric element. The differently doped cuboids are connected to one another by the metal bridges in such a manner that they produce a series circuit.

If an electric current, is supplied to the cuboids the connecting points of the cuboids on one side cool down depending on the current intensity and current direction, while they heat up on the opposite side. The applied current thus produces a temperature difference between the ceramic plates. If, however, a different temperature is applied to the opposite ceramic plates, a current flow is produced in the cuboids of the thermoelectric element depending on the temperature difference.

The edge lengths of the cuboids in all directions are approximately 1-3 mm. The shape of the cuboids roughly approximates a dice. The considerable thickness of the cuboids is required since they are not only used to achieve the thermoelectric effect but also ensure the mechanical stability of the thermoelectric element. In particular, the ceramic plates on the hot and cold sides of the thermoelectric element are supported on the metal bridges used as connecting points. The cuboids therefore require a large amount of semiconductor material which is not heeded to achieve the thermoelectric effect. Consequently, the electrical and thermal power density based on the mass of known thermoelectric elements is relatively low even though the thermal power density based on the area of the thermoelectric modules is too high for most uses.

US 2007/0152352 A1 discloses a thermoelectric apparatus having a plurality of thermocouples each consisting of an n-doped thermocouple leg and a p-doped thermocouple leg made of semiconductor material. The thermoelectric apparatus comprises a frame-like supporting structure which surrounds an opening. A substrate is arranged in this opening in the supporting structure. The substrate is used to accommodate an electronic unit, the temperature of which is deliberately intended to be kept above or below the ambient temperature with the aid of the thermoelectric apparatus. A thermally insulating structure on which the thermocouple legs of all thermocouples are exclusively arranged is situated between this substrate and the supporting structure surrounding the substrate. During operation of the thermoelectric apparatus, current flows through the thermocouples connected in series. The current flow causes thermal energy to be transferred from the substrate to the supporting structure through the thermally insulating structure, as a result of which the substrate and the electronic unit arranged on the latter are cooled.

On the basis of this prior art, the invention is based on the object of providing a thermoelectric element with a high thermal power density based on the mass, which element nevertheless ensures sufficient mechanical stability with less semiconductor material. The absolute thermal bower and power density of the thermoelectric elements and of the modules produced from the latter are intended to be able to be readily adapted to the thermal powers and power densities arising during their use.

The achievement of this object is based on the concept of splitting the thermoelectric effect and the supporting function of the cuboids between two components. A multi-part carrier undertakes the supporting function, while the thermoelectric effect comes from thermocouple legs arranged on the carrier.

In detail, the object is achieved in the case of a thermoelectric element of the type mentioned at the outset by virtue of the fact that

(a) the carrier has a first carrier part and a second carrier part with high thermal conductivity,

(b) the first and second carrier parts are separated from one another by a section having a thermal conductivity lower than the carrier parts,

(c) the thermocouple legs arranged on the carrier extend between the first and second carrier parts and bridge the section with the lower thermal conductivity, one of the carrier parts forming the hot side of the thermoelectric element and the other carrier part forming the cold side of the thermoelectric element.

The carrier may consist of cheaper material which is mechanically more stable than the semiconductor material, with the result that the carriers require a smaller installation space with the same mechanical stability. The carrier which is preferably in the form of a cuboid may have, for example, a smaller thickness than the conventional semiconductor cuboids if more stable materials are used.

The thermocouple legs of the thermocouple are preferably

arranged on the carrier in the form of a layer, in particular in the form of a thin layer or a film. Therefore, considerably less semiconductor material than in conventional thermoelectric elements is required.

In order to allow the temperature difference between the hot and cold sides of the thermoelectric element to become effective primarily in the thermocouples, the first and second carrier parts are separated from one another by the section with lower thermal conductivity. The thermocouple legs of the thermocouples extend between the first and second carrier parts and bridge the section with lower thermal conductivity.

The section with lower thermal conductivity thermally decouples the two carrier parts, with the result that one carrier part forms the hot side of the thermoelectric element and the other carrier part forms the cold side of the thermoelectric element.

The section separating the two carrier parts may completely or partially consist of an insulating material. If the separating section only partially consists of the insulating material, the remaining part of the section between the first and second carrier parts is formed by the ambient gas, in particular the ambient air which has a low thermal conductivity of 0.0261 W/m*K.

Another possible way of reducing the thermal conductivity in the section between the two carrier parts involves connecting the two carrier parts to one another by means of at least one web. The cross section of the webs, which is small in relation to the carrier parts, forms a thermal resistance and thus reduces the thermal conductivity in the section. In terms of production, in the case of a cuboidal carrier, the webs which are in particular, cuboidal are situated. approximately centrally on two opposite surfaces of the cuboid. A gas, in particular the ambient air, with lower thermal conductivity than the first and second carrier parts is situated in the passage between the webs which is likewise cuboidal.

Even more effective thermal decoupling between the first and second carrier parts is achieved if the web or the connecting webs consist (s) of a material with lower thermal conductivity than the carrier parts. Added to the reduced thermal conductivity of the section on account of the reduced cross section of the webs is then also the material-induced reduction in the thermal conductivity.

If the section with lower thermal conductivity partially has passages, the arrangement of the thermocouple legs on the carrier is facilitated if they are applied to a substrate with low thermal conductivity and that surface of the substrate which has the thermocouple legs is arranged on the carrier. In the region bridging the passages, the substrate undertakes the supporting function for the thermocouple legs of the thermocouples. The substrate may consist, for example, of glass which has a thermal conductivity of 0.76 W/m*K.

As in conventional thermoelectric elements, the differently doped thermocouple legs are connected in series.

In order to reduce the electrical terminal resistance, the thermocouple legs connected in series on the cold side are connected to the two electrical contacts. The contacts are preferably arranged as contact regions on the surface of the carrier part or are embedded in the surface thereof.

In order to electrically connect a multiplicity of thermoelectric elements according to the invention to one another, in particular to combine them in a module, one of the two contacts on the cold side preferably has a plated-through hole which leads to a contact on the opposite side of the carrier part. The contact on the opposite side may likewise be applied to the surface of the carrier part or may be set into the surface of the latter.

Suitable materials for the carrier, and the first and second carrier parts are, in particular, technical ceramic materials. The ceramic materials have the required high thermal conductivity with simultaneously good electrical insulating ability which is needed to avoid short circuits between the thermocouples connected in series. Furthermore, ceramic materials are highly thermostable and have the resistance to temperature changes which is desirable for thermoelectric elements. The strength, hardness and dimensional stability of ceramic materials are advantageous for the supporting function. The corrosion resistance and wear resistance of ceramic materials take account of the wish for durable thermoelectric elements.

The ceramic carrier, in particular the first and second. carrier parts, preferably consists of a multilayer low-temperature co-fired ceramic. Low-temperature co-fired ceramics (LTCC) are based on a technology for producing multilayer ceramic carriers. Ceramic powder is first of all processed, together with solvents and plasticizers, to form films. The unfired films are structured by punching, cutting and, if appropriate, printing. In order to produce plated-through holes, through-holes, for example, are punched into the ceramic films or are cut with the laser.

The individual layers of the structured ceramic film are aligned and are stacked in a press mold. The through-holes are filled with a conductive baste, in particular a silver, silver/palladium or gold paste. The advantage of these conductive pastes is that they shrink to virtually the same extent as the ceramic films during subsequent firing. The ceramic films are laminated with the supply of heat, for example 70 degrees Celsius, and pressure, for example 90 bar. During subsequent firing of the ceramic films, the individual layers of the ceramic films are permanently connected to one another.

In order to improve the thermal conductivity, layers for improving the thermal conductivity of the carrier parts can be embedded in the multilayer low-temperature co-fired ceramic. Suitable layers are, in particular, metallization layers but also layers of silicon, aluminum nitrite or aluminum oxide. The layers of aluminum nitrite and aluminum oxide improve the thermal conductivity but are electrically insulating. They are therefore used, in particular, on the hot side of the thermoelectric element. The embedded layers and the ceramic films are connected, for example, by means of reactive solder or glass solder. The thermal conductivity can additionally be improved by passages which, like the plated-through holes, are filled with metallic materials.

In order to increase the electrical output power, a plurality of thermoelectric elements according to the invention can be electrically and mechanically connected to one another in a module. The thermoelectric elements forming the module are preferably in the form of plate-shaped cuboids which are combined to form a stack. Each thermoelectric element of the module preferably has contact-making means on the opposite sides of the plate shaped carrier part on the cold side, which contact-making means come into contact with the contact-making means of the respective adjacent plate-shaped thermoelectric element, with the result that the thermoelectric elements of the module are connected in series or in parallel.

The invention is explained in more detail below using the figures, in which:

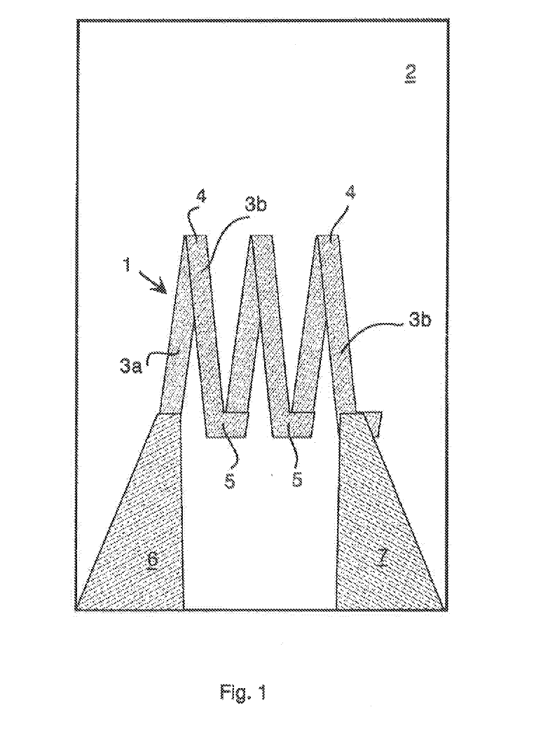

FIG. 1 shows thermocouples formed as a layer on a substrate for a thermoelectric element according to the invention,

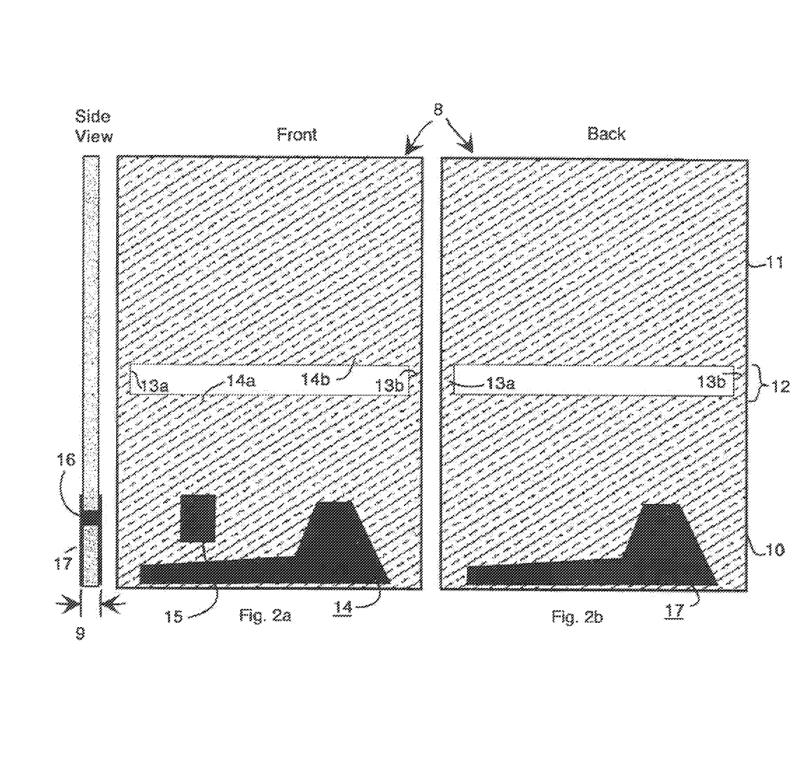

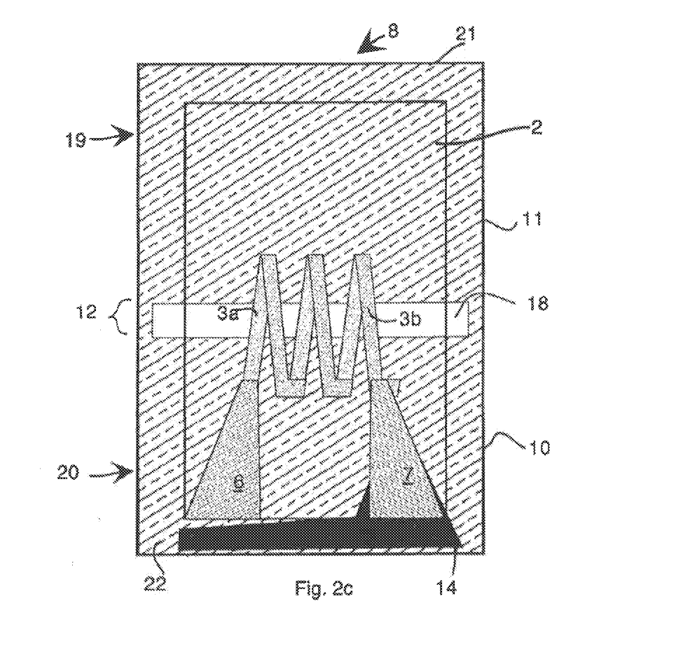

FIG. 2a shows a front view and a side view of a carrier of the thermoelectric element,

FIG. 2b shows a rear view of the carrier of the thermoelectric element according to the invention,

FIG. 2c shows a plan view of thermoelectric element according to the invention,

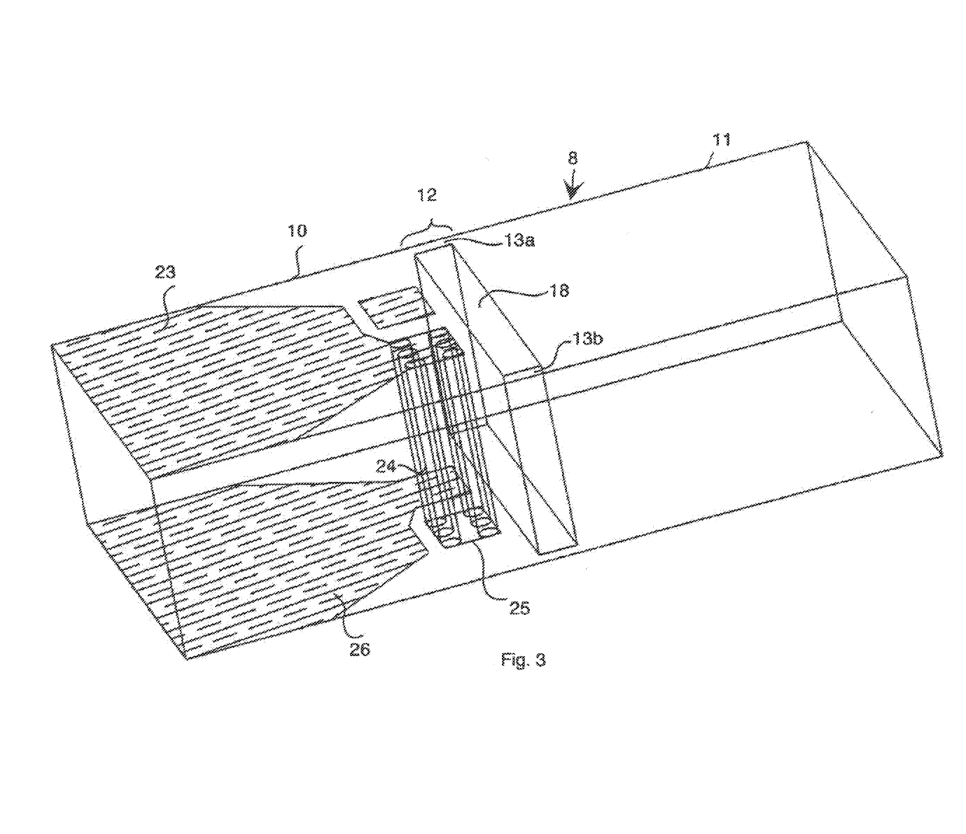

FIG. 3 shows a schematic perspective view of a second exemplary embodiment of a thermoelectric element, in which the thermocouple legs are arranged on one side of the carrier,

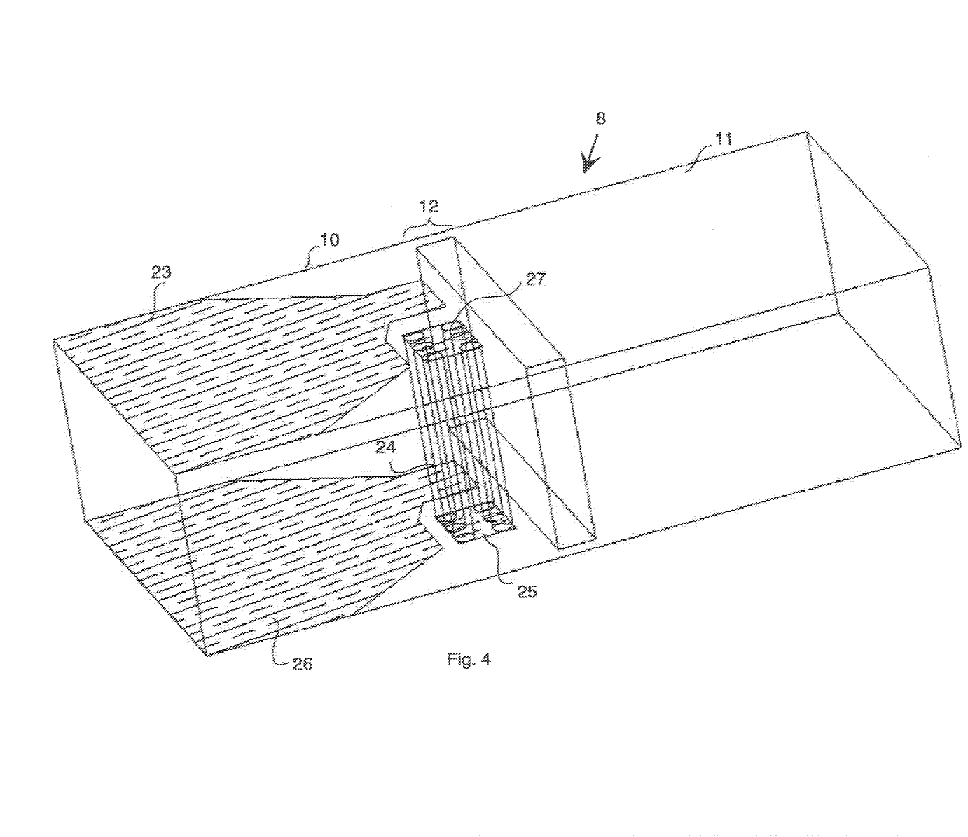

FIG. 4 shows a schematic perspective view of a third exemplary embodiment of a thermoelectric element, in which the thermocouple legs are arranged on two opposite sides of the carrier,

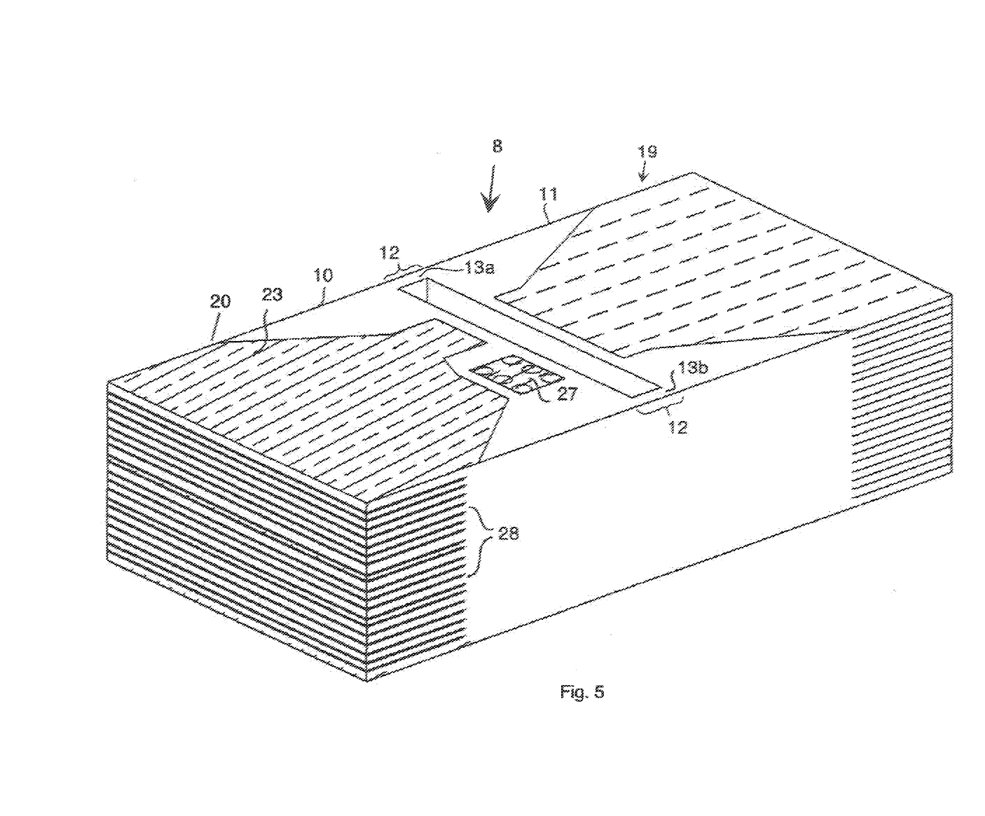

FIG. 5 shows a thermoelectric element according to FIG. 4 with improved thermal conductivity,

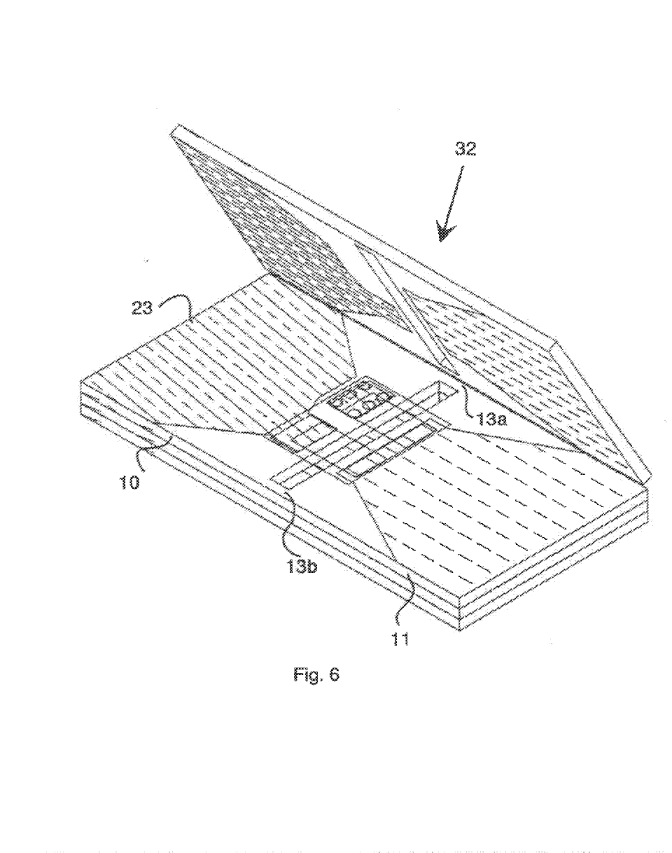

FIG. 6 shows a plurality of thermoelectric elements which have been combined to form a stack, and

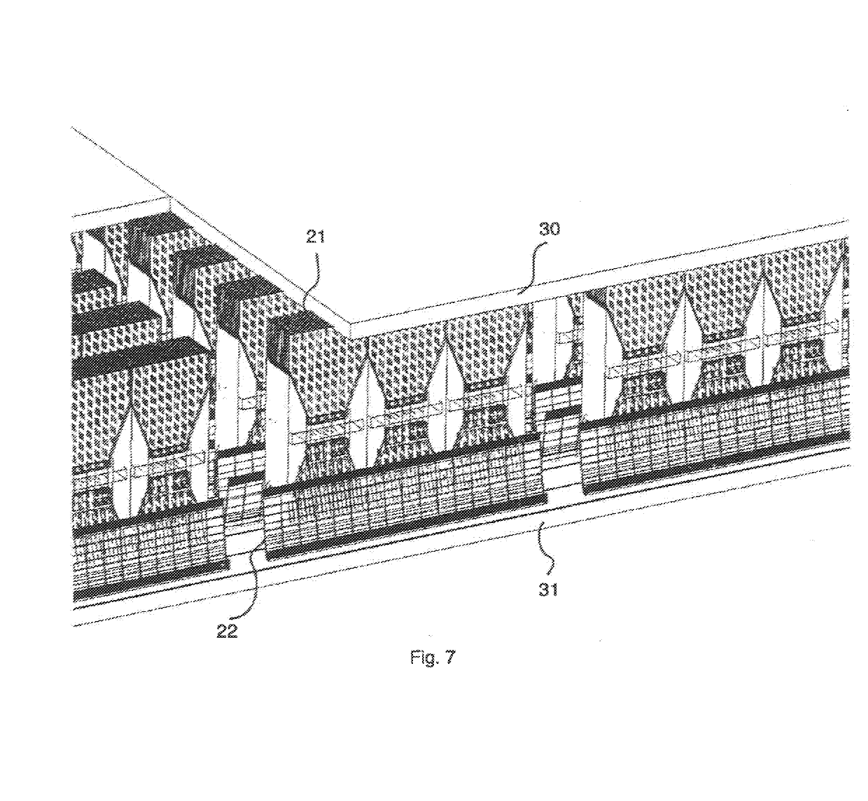

FIG. 7 shows a possible way of arranging a plurality of the elements between two ceramic plates arranged at a distance from one another in order to construct a module.

FIG. 1 shows three thermocouples (1) which have been applied to a substrate (2) as a layer. The substrate (2) is, for example, a rectangular glass plate having a low thermal conductivity. Each thermocouple (1) comprises an n-doped thermocouple leg (3a) and a p-doped thermocouple leg (3b) made of a semiconductor material. The n-doped and p-doped thermocouple legs (3a, b) are electrically connected in series at opposite connecting points (4, 5).

The series circuit comprising then-doped and p-doped thermocouple legs (3a, b) is connected, at its input and output, to two electrical contacts (6, 7) which have been applied, as contact regions, to the surface of the substrate (2) as a metallic layer.

FIGS. 2a, 2b show a carrier (8) of the thermoelectric element according to the invention. The carrier (8) overall has the shape of a cuboid. It is possible to see from the side view illustrated in FIG. 2a that its thickness (9) is relatively low on account of the separation of the supporting function and the thermoelectric effect. The carrier (8) comprises a first carrier part (10) and a second carrier part (11) with high thermal conductivity. The carrier parts preferably consist of a technical ceramic material. The two carrier parts (10, 11) are separated from one another by a section (12) having a lower thermal conductivity than the carrier parts. The section (12) has two webs (13a, b) which connect the first and second carrier parts (10, 11) and connect the two carrier parts (10, 11) to one another in an extension of the side surfaces, If the webs (13a, b) consist of the same material as the carrier parts (10, 11), the thermal conductivity is considerably reduced on account of the smaller cross section of the webs (13a, b) in comparison with the cross section of the carrier parts (10, 11). The section (12) also has the gap which is bounded laterally by the webs (13a, b) and by the end faces (14a, b) of the first and second carrier parts (10, 11) and contains ambient air which has a lower thermal conductivity than the carrier parts (10, 11) and therefore thermally decouples the latter.

Contacts (14, 15) which are in the form of contact regions and are intended to make electrical contact with the thermocouples (1) connected in series are situated on the front side of the carrier (8). The contact (15) is connected in an electrically conductive manner to a contact (17) on the rear side of the carrier (8) via a plated-through hole (16). The large-area contacts (14, 17) on the front and rear sides of the first carrier part (10) of the carrier (8) allow contact to be easily made with the thermoelectric element and allow connection to further identical thermoelectric elements.

FIG. 2c illustrates how that surface of the substrate (2) which has the thermocouple legs (3a, b) is arranged on the carrier (a), The contacts (6, 7) come into contact with the contacts (14, 15) on the top side of the carrier (8), with the result that the contact (6) is connected to the contact (17) on the rear side via the plated-through hole (16). The thermocouple legs (3a, b) of the thermocouples (1) extend between the first and second carrier parts (10, 11) and in the process bridge the air cap (18) of the section (12) with lower thermal conductivity. The second carrier part (11) forms the hot side (19) of the thermoelectric element and the first carrier part (10) forms the cold side (20) of the thermoelectric element. Heat is introduced, an particular, at the upper edge (21) of the second carrier part (11), while a heat sink is arranged on the lower edge (22) of the first carrier part (10). Like in conventional thermoelectric elements, the upper and lower edges (21, 22) of a multiplicity of thermoelectric elements may be arranged between ceramic plates (30, 31) running perpendicular to the plane of the drawing, as illustrated in FIG. 7. The mechanical stability of the carrier (8) suffices to keep the ceramic plates (30, 31) at a distance despite thermoelectric thin-film technology.

FIG. 3 shows a ceramic carrier (8) in which the first and second carrier parts (10, 11) and the webs (13a, b) of the section (12) consist of a multilayer low-temperature co fired ceramic. A contact (23) which is connected to a contact on the rear side of the carrier (8) is a plated-through hole (24) is situated on the front, side of the carrier (8) which faces upward. A large-area contact (26) which, like the contact (25) as well, is intended to connect the thermocouple legs (3a, b) connected in series is also situated on the rear side. The thermocouple legs (3a, b) connected in series are connected to the two contacts (25, 26) on the rear side and extend from the first carrier part (10) on the cold side to the second carrier part (11) on the hot side and bridge the air gap (18) of the section (12). The thermocouple legs (3a, b) are preferably arranged on a substrate. Alternatively, the thermocouple legs may be part of a film which cc bridge the air gap (18) without an additional, substrate on account of its inherent rigidity.

FIG. 4 shows a carrier (8) on whose front and rear sides the thermocouple legs (3a, b) of a plurality of thermocouples (1) are arranged. All thermocouple legs (3a, b) are connected in series. The carrier (8) has the contact (23) and the contact (27) on the top side, a plated-through hole (24) which starts from the contact (27) and is connected to a contact (25) on the rear side, and the contact (26) on the rear side.

The thermocouple legs (3a, b) connected in series on the top side of the carrier (8) are connected, at the ends, to the contacts (23, 27). The thermocouple legs (3a, b) connected in series are connected to the electrical contacts (25, 26) on the underside, the plated-through hole (24) establishing the electrically conductive connection between the thermocouple legs (3a, b) on the top side and underside of the carrier (8).

In the same manner as in the carrier according to FIG. 3, a plurality of thermoelectric elements can be connected in series or else in parallel via the large-area contacts (23, 26).

In terms of making contact with the thermocouple lags (3a, b), the carrier according to FIG. 5 corresponds to the carrier according to FIG. 4, with the result that reference is made in full to the statements made there. However, the thermal conductivity both on the hot side. (19) and on the cold side (20) of the carrier (8) is improved by embedding metallization layers (28). On the of side (19), the top side and underside of the carrier (8) are free of metallizations so that short circuits do not occur between the thermocouple legs (3a, b) resting on the top side and underside. Alternatively, on the hot side, layers of silicon, aluminum nitrite or aluminum oxide may be embedded in the second carrier part (10) in order to improve the thermal conductivity but to avoid short circuits between the thermocouple legs (3a, b).

On the cold side (20) as well, it is necessary to ensure that no metallizations on the underside and top side cause short circuits between the thermocouple legs (3a, b) outside the contact regions (23, 25, 26, 27). It can also be seen from FIG. 5 that the section (12) with lower thermal conductivity is free of metallizations. The thermal conductivity of the webs (13a, b) is consequently reduced not only by the smaller cross section but also by the lack of metallization.

FIG. 6 finally discloses a stack (32) comprising a plurality of thermoelectric elements which are electrically connected in series and are constructed in a manner corresponding to FIG. 3 but have a smaller thickness. A plurality of such stacks (32) can be combined to form a module (29) corresponding to FIG. 7.

List of reference symbols

| No. | Designation |
|---|---|
| 1 | Thermocouple |
| 2 | Substrate |
| 3a | n-doped thermocouple leg |
| 3b | p-doped thermocouple leg |
| 4 | Connecting point |
| 5 | Connecting point |
| 6 | Contact |
| 7 | Contact |
| 8 | Carrier |
| 9 | Thick carrier |
| 10 | First carrier part |
| 11 | Second carrier part |
| 12 | Section |
| 13a, b | Webs |
| 14 | Contact |
| 15 | Contact |
| 16 | Plated-through hole |
| 17 | Contact |
| 18 | Air gap |
| 19 | Hot side |
| 20 | Cold side |
| 21 | Upper edge |
| 22 | Lower edge |
| 23 | Contact |
| 24 | Plated-through hole |
| 25 | Contact |
| 26 | Contact |
| 27 | Contact |
| 28 | Metallization layers |
| 29 | Module |
| 30 | First ceramic plate |
| 31 | Second ceramic plate |
| 32 | Stack |

1-13. (canceled)

14. A thermoelectric element, comprising:
at least one thermocouple made from a semiconductor material and having thermocouple legs including an n-doped thermocouple leg and a p-doped thermocouple leg, the thermocouple legs extending between a hot side and a cold side of the thermoelectric element, wherein different temperatures are capable of being applied to or tapped off of the hot and cold sides of the thermoelectric element;
a carrier having a first carrier part and a second carrier part, each having a high thermal conductivity, and a section separating the first and second carrier parts, the section having a thermal conductivity that is lower than that of the first and second carrier parts,
wherein the thermocouple legs are arranged on the carrier, extend between the first and second carrier parts, and bridge the section separating the first and second carrier parts, one carrier part of the first and second carrier parts comprising the hot side of the thermoelectric element and the other carrier part of the first and second carrier parts comprising the cold side of the thermoelectric element; and
a substrate with low thermal conductivity, wherein the thermocouple legs are applied to a surface of the substrate and the surface of the substrate with the thermocouple legs rests on the carrier.

15. The thermocouple element of claim 14, wherein the thermocouple legs are in the form of a layer.

16. The thermocouple element of claim 14, wherein the thermocouple legs are in the form of a film.

17. The thermocouple element of claim 14, wherein the section separating the first and second carrier parts comprises at least one web connecting the first and second carrier parts.

18. The thermocouple element of claim 14, wherein at least a part of the section separating the first and second carrier parts is an insulating material.

19. The thermocouple element of claim 14, wherein the thermocouple legs connected in series on the cold side of the thermocouple element are connected to at least two electrical contacts.

20. The thermocouple element of claim 19, wherein a first contact of the at least two electrical contacts is connected to a plated-through hole that is connected to another contact on a side of the carrier that is opposite the first contact.

21. The thermocouple element of claim 14, wherein the first and second carrier parts consist of ceramic.

22. The thermocouple element of claim 21, wherein the first and second carrier parts consist of a multilayer low-temperature co-fired ceramic.

23. The thermocouple element of claim 14, further comprising layers for improving the thermal conductivity embedded in the first and second carrier parts.

24. A module comprising a plurality of thermoelectric elements electrically connected to one another, each of the thermoelectric elements being a thermoelectric element as recited in claim 14.

25. The module of claim 24, wherein the thermoelectric elements are plate-shaped and are arranged in a stack.
